(19) United States
(12) Patent Application Publication
(10) Pub. No.: US 2013/0241381 A1
(43) Pub. Date: Sep. 19, 2013

(54) ONE-PIECE CASE FOR ENCLOSING A TABLET-COMPUTING DEVICE

(71) Applicants: Bryan Lee Hynecek, Redwood City, CA (US); Jarret Weis, San Francisco, CA (US); Jon Dukerschein, San Francisco, CA (US)

(72) Inventors: Bryan Lee Hynecek, Redwood City, CA (US); Jarret Weis, San Francisco, CA (US); Jon Dukerschein, San Francisco, CA (US)

(73) Assignee: SPECULATIVE PRODUCT DESIGN, LLC, Mountain View, CA (US)

(21) Appl. No.: 13/614,538

(22) Filed: Sep. 13, 2012

Related U.S. Application Data
(60) Provisional application No. 61/536,976, filed on Sep. 20, 2011.

(51) Int. Cl. H05K 5/02

(52) U.S. Cl. CPC H05K 5/0239; H05K 5/0217
USPC 312/240; 312/326

(57) ABSTRACT

A one-piece case for enclosing a computing device such as a tablet computer is molded from a single material into a single piece. The case comprises a base portion to hold the computing device and a cover portion to cover the front or screen of the computing device. By varying the thickness of the material used in different areas of the one-piece case, the two portions of the case may be hinged together. Similarly, because of the areas of differing thicknesses, the cover portion of the one-piece case can be folded into various configurations, thereby creating a stand for the computing device.

### CROSS-REFERENCE

The present application claims the benefit of U.S. Provisional Application No. 61/536,976 filed Sep. 20, 2011, which is incorporated herein by reference in its entirety.

### BACKGROUND

1. Field Of Invention

The present disclosure relates generally to protective cases for an electronic device and specifically to a one-piece protective case for a tablet-type computing device.

2. Description Of The Background

Smart phones, tablet computers, personal readers, personal electronic assistants, as well as other portable electronic devices are widely used and have become a ubiquitous part of every day life. Such devices, although designed to be used in real world environments, often contain sensitive electronics and are subject to damage if dropped from a normal operating position. Many devices contain interactive touchscreen type displays made of glass or other brittle materials. The electronic devices, typically do not come with any sort of built in or integral cases or covers to protect the screens or the backs and sides of the devices. Despite attempts to design these complicated electronic devices for real world application, it is often necessary to utilize some form of protective case to shield and protect the electronic devices from damage due to drops or falls. Many different types and designs of cases exist and provide a wide range of protections and features. Cases may range from purely decorative to utilitarian, from soft pliable cases, to co-molded soft and hard cases to rigid cases. Cases, for tablet computers for example, are often comprised of two distinct and separate pieces, a cover for the front of the device, and some form of case or shell for the back of the device. These cases are typically comprised of many components joined together by various means. Manufacturing these cases from individual components adds time and cost to the manufacturing process and introduces weakness and points of failure into the overall case. It is therefore desirable to have a case that is molded from a single piece of material yet provides the functionality of a multi-piece case that covers both the front and back of the device. The present inventions fulfills this need. The one-piece case and molding process of the present disclosure offers considerable advantages over other available methods and the one-piece construction removes the need to join components of a case together, provides an attractive look and feel, and provides increased durability over other cases that require joining different materials together.

### SUMMARY

The present invention provides a case that is molded to form a single piece from a single material, such as such as plastic, rubber, elastomeric material, a thermoplastic polyurethane (TPU) and/or a thermoplastic elastomers (TPE) and/or some combination thereof. The one-piece molding case and process offers considerable advantages over presently available methods. For example, the one-piece construction removes the need to join components of a case together, provides an attractive look and feel, and provides increased durability over other cases that require joining different materials together.

In an embodiment of the present disclosure, a one-piece molded case for enclosing a computing device is disclosed. The one piece case comprise a first portion shaped to accept and retain the computing device when inserted therein, where the first portion substantially covers a bottom and a side surface of the inserted computing device. The case further includes a second portion shaped to fold over the first portion and cover a top of the inserted computing device.

In another embodiment, the one-piece molded case further comprises a junction between the first and second portions, wherein the first portion and the second portion have a first thickness and the junction has a second thickness that is thinner than the first thickness. In another embodiment, the junction acts as a hinge between the first portion and the second portion. In another embodiment, the second portion has a plurality of segments and a plurality of junctions, and the plurality of segments has the first thickness and the plurality of junctions has the second thickness, and the first thickness is greater then the second thickness.

In another embodiment, adjacent segments of the plurality of segments are separated by one of the plurality of junctions. In still another embodiment, the second portion bends at the plurality of junctions to reform into a shape of a stand.

In another embodiment, the second portion has an inner surface and an outer surface, and the outer surface of the second portion has a textured portion. In still another embodiment, the second portion comprises a closing portion for retaining the second portion adjacent to the top of the computing device. In another embodiment, the second portion comprises a portion of a sensor for interacting with the computing device when the second portion is adjacent to the top of the computing device.

In another embodiment, the case is formed from at least plastic, rubber, silicone, neoprene, elastomeric material, a thermoplastic polyurethane (TPU) and a thermoplastic elastomers (TPE). In still another embodiment, the computing device is a tablet computer.

In another embodiment, a case with an integrated stand for a tablet computing device is disclosed. The case with the integrated stand comprises a first portion shaped to accept and retain the tablet computing device when inserted therein, the first portion substantially covering a bottom and a side surface of the inserted computing device and a second portion capable of being configured into a plurality of shapes, where at least one of the plurality of shapes is the integrated stand for the tablet computing device.

In still another embodiment, of the case with an integrated stand for a tablet computing device the second portion comprises a plurality of segments separated by a plurality of junctions, and at least one of the plurality of junctions acts as a hinge between two adjacent segments of the plurality of segments. In still another embodiment, the plurality of segments has the first thickness and the plurality of junctions has the second thickness, and the first thickness is greater then the second thickness.

### BRIEF DESCRIPTION OF THE DRAWINGS

The devices and methods described herein are further described in terms of exemplary embodiments. These exemplary embodiments are described in detail with reference to the drawings. These embodiments are non-limiting exemplary embodiments, in which like reference numerals represent similar structures throughout the several views of the drawings, and wherein:

FIG. 1 depicts a perspective view of a one-piece case in accordance with an embodiment of the present disclosure;

FIG. 2 depicts a cross sectional view of a one-piece case in accordance with an embodiment of the present disclosure;

FIG. 3 depicts a perspective view of a one-piece case with an inserted device in accordance with an embodiment of the present disclosure

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, and/or components, have been described at a relatively high-level, without detail, in order to avoid unnecessarily obscuring aspects of the present teachings.

A one-piece case for enclosing a computing device such as a tablet computer is molded from a single material into a single piece. The case comprises a base portion to hold the computing device and a cover portion to cover the front or screen of the computing device. By varying the thickness of the material used in different areas of the one-piece case, the two portions of the case may be hinged together. Similarly, because of the areas of differing thicknesses, the cover portion of the one-piece case can be folded into various configurations, thereby creating a stand for the computing device. The PixelSkin HD Wrap™ for iPad2™ from Speculative Products LLP (SPECK), is an example of just such a case.

The case of the present disclosure is molded to form a single piece from a single material, such as plastic, rubber, silicone, neoprene, elastomeric material, a thermoplastic polyurethane (TPU) and/or a thermoplastic elastomers (TPE) and/or some combination thereof. It is a one-piece case which incorporates both a front and back portion, intended to cover the screen and rear of a device, into a single one piece design. While, the present disclosure makes reference to a tablet computer, it is to be understood by those skilled in the art, that a case of the present disclosure may be utilized with any type of personal electronic device, where the user wishes to protect the front and back of the device with a case made from a unitary piece of material. Such devices include, but are not limited to tablet computers, smart phones, book readers, PDAs, handheld game systems, or any other electronic device that is configured without an integral cover.

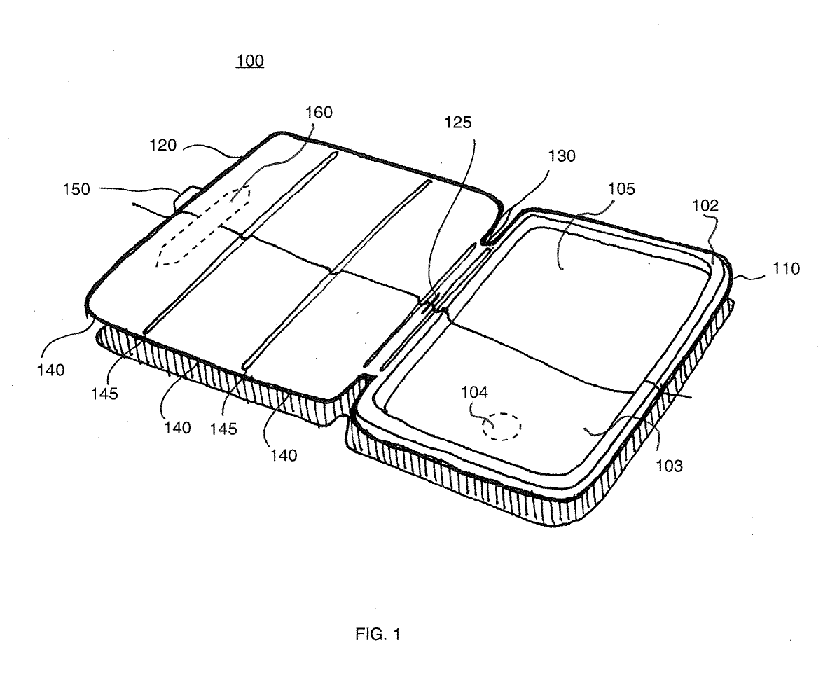

FIG. 1 depicts an embodiment of a one-piece case 100 in accordance with the present disclosure. One-piece case 100 comprises a first portion 110 and a second portion 120. First portion 110 may be shaped to accept and retain an inserted electronic device such as a tablet-computing device (not shown). In an embodiments, a computing device may be inserted into cavity 105 in first portion 110 and held in place via any known means such as, but not limited to, a clip, an overhanging extension, a detent, a lip, an adhesive, a magnet, a strap, a hook and loop mechanism such as Velcro^{TM} , or high friction materials. Any of these materials may be attached to, or incorporated into, the case in order to retain an inserted tablet-computing device in cavity 105. Cavity 105 in first portion 110 may have sides 102 that extends around the entire cavity 105 or sides 102 may only partially surround cavity 105. First portion 110 may have bottom portion 103 which covers the entire bottom of cavity 105 or bottom portion 103 may only cover a partial portion of cavity 105. Additionally, case 100 may be customized to accommodate a particular kind or type of tablet or computing device and bottom portion 103 or any other part of first portion 110 including sides 102 may include one or more apertures 104 to accommodate a feature of the inserted tablet-computing device, such as, but not limited to, a user interface or a port, a camera, a speaker or an access panel.

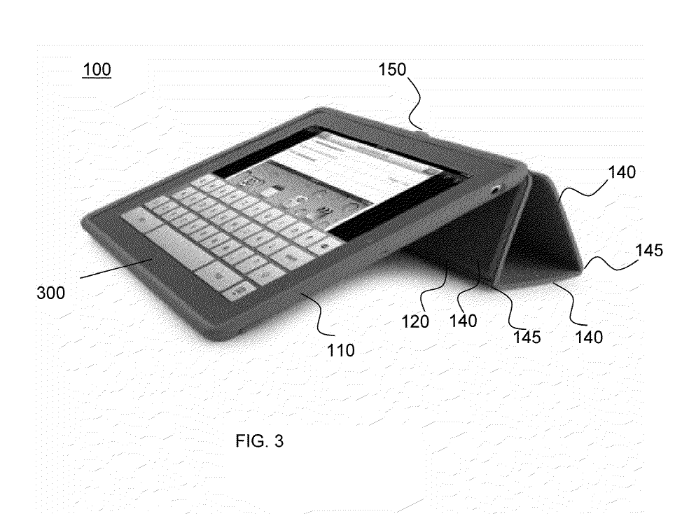

Second portion 120 may include two or more segments 140 separated by a relatively thin junction 145. Thin junction 145 may allow for flexibility between the segments such that second portion 120 may be folded along one or more thin junctions 145 in order to, for example, elevate the tablet-computing device at an angled position relative to a planar position and/or maintain tablet-computing device in the angled position. FIG. 3 shows case 100 with a computing device 300 inserted. As shown, first portion 110 houses computing device 300 in cavity 105 and second portion 120 is presented in a folded position, to present computing device 300 in an elevated position.

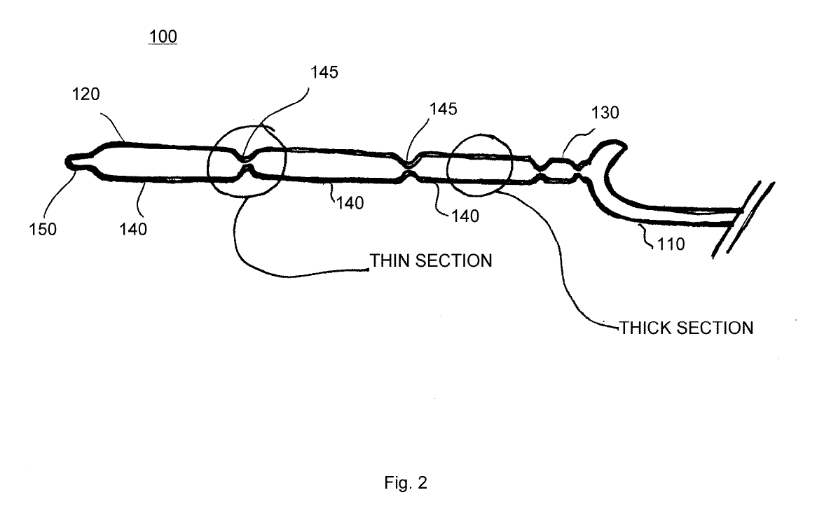

As seen in FIG. 2, first portion 110 may be joined to second portion 120 of case 100 via hinge junction 130. Hinge junction 130 may be sufficiently thin so as to allow flexibility between first and second portions 110 and 120 such that second portion 120 may be folded over first portion 110 and/or an enclosed tablet-computing device in order to cover a surface of the enclosed tablet-computing device. Hinge junction 130 may be made of the same material as the remainder of case 100 or may comprise additional reinforcement materials such as mesh or film, molded into hinge junction 130 to provide additional strength. In some embodiments, case 100 may also include an extension or tab 150 that may be inserted into an opening or slot 125 when folded in order to, for example, maintain the folded arrangement of segments 140. Other methods to maintain the folds may also be employed, such as magnets, hook and loop, friction, or snaps.

As understood by one skilled in the art, case 100 is molded as one continuous piece comprising both first portion 110 and second portion 120. While case 100 is a single unit, it relies on different thicknesses of materials in different portions to contribute to the overall functionality and flexibility of the different sections. For example, thin junctions 145 and hinge junction 130 while made of the same material as segments 140 and first portion 110 are considerably thinner and provide flexibility to facilitate bending and opening and closing of second portion 120. Furthermore, junctions 145 and hinge junction 130 may be the same thicknesses or different thicknesses

In one embodiment, case 100 may have a closing mechanism 160 by which it closes and/or remains closed. In an embodiment, closing mechanism 160 may be a portion, of and/or affixed to, an inner surface of second portion 120 and may interface with, for example, an inserted tablet-computing device and/or first portion 110. For example, the closing mechanism may be a high-friction material and when the second portion 120 is folded over first portion 110, the high friction material may affix to an upper surface of an enclosed tablet-computing device and thereby may maintain a folded and/or closed position. The closing mechanism 160 may also be a high suction mechanism which adheres to the surface of the inserted computing device. The closing mechanism 160 may be a magnet or ferric material and may interact with a complementary mechanism incorporated into the computing device or into first portion 110. The closing mechanism 160 may also be used as part of a sensor incorporated into the computing device, which allows the device to turn off or enter a sleep mode when the second portion 120 is closed over the computing device.

Additionally and/or alternatively, textures, graphics, coloration, or other features may be incorporated into the molding of first portion 110 or second portion 120. For example, different colors may be added to the materials to create graphics or patterns, or the molds used to form the case 100 may contain graphics, logos, images, textures, such as ridges, which transfer to either first portion 110 or second portion 120 during the molding process.

Those skilled in the art will recognize that the present teachings are amenable to a variety of modifications and/or enhancements. While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

1. A one-piece molded case for enclosing a computing device, the case comprising:
a first portion shaped to accept and retain the computing device when inserted therein, the first portion substantially covering a bottom and a side surface of the inserted computing device; and
a second portion shaped to fold over the first portion and cover a top of the inserted computing device.

2. The one-piece molded case of claim 1, comprising:
a junction between the first and second portions,
wherein the first portion and the second portion having a first thickness and the junction has a second thickness that is thinner than the first thickness.

3. The one-piece molded case of claim 2 where the junction acts as a hinge between the first portion and the second portion.

4. The one-piece molded case of claim 2 where the second portion has a plurality of segments and a plurality of junctions,
wherein the plurality of segments has the first thickness and the plurality of junctions has the second thickness, and
wherein the first thickness is greater then the second thickness.

5. The one-piece molded case of claim 4 wherein adjacent segments of the plurality of segments are separated by one of the plurality of junctions.

6. The one-piece molded case of claim 5, wherein the second portion bends at the plurality of junctions to reform into a shape of a stand.

7. The one-piece molded case of claim 1 wherein the second portion has an inner surface and an outer surface, and
wherein the outer surface of the second portion has a textured portion.

8. The one-piece molded case of claim 1 wherein the second portion comprises a closing portion for retaining the second portion adjacent to the top of the computing device.

9. The one-piece molded case of claim 1 wherein the second portion comprises a portion of a sensor for interacting with the computing device when the second portion is adjacent to the top of the computing device.

10. The one-piece molded case of claim 1 formed from at least one of the following:
plastic, rubber, silicone, neoprene, elastomeric material, a thermoplastic polyurethane (TPU) and a thermoplastic elastomers (TPE).

11. The one-piece molded case of claim 1 wherein the computing device is a tablet computer.

12. A case with an integrated stand for a tablet computing device comprising:
a first portion shaped to accept and retain the tablet computing device when inserted therein, the first portion substantially covering a bottom and a side surface of the inserted computing device;
a second portion capable of being configured into a plurality of shapes, wherein at least one of the plurality of shapes is the integrated stand for the tablet computing device.

13. The case of claim 12 wherein the second portion comprises a plurality of segments separated by a plurality of junctions, and
wherein at least one of the plurality of junctions act as a hinge between two adjacent segments of the plurality of segments.

14. The case of claim 13 wherein the plurality of segments has the first thickness and the plurality of junctions has the second thickness, and wherein the first thickness is greater then the second thickness.
